(19) United States
(12) Patent Application Publication
(10) Pub. No.: US 2021/0360786 A1
(43) Pub. Date: Nov. 18, 2021

(54) METHODS FOR PRINTING CONDUCTIVE INKS AND SUBSTRATES PRODUCED THEREOF

(71) Applicant: SCHMUTZ IP, LLC, Lawrenceville, GA (US)

(72) Inventor: Daniel SLEP, Stony Brook, NY (US)

(21) Appl. No.: 17/283,978

(22) PCT Filed: Oct. 10, 2019
(86) PCT No.: PCT/US2019/055664

§ 371 Date: Apr. 9, 2021

Related U.S. Application Data
(60) Provisional application No. 62/744,253, filed on Oct. 11, 2018.

(51) Int. Cl. H05K 1/09; C09D 11/52; H05K 3/12; B33Y 70/10

(52) U.S. Cl. CPC H05K 1/097; C09D 11/52; B82Y 40/00; B33Y 70/10; H05K 3/125

(57) ABSTRACT

Described herein are methods for printing conductive ink on a substrate. In one embodiment, the method for printing a conductive ink on a substrate, comprises (a) printing, using a printer, one or more layers of a non-conductive material on a surface of the substrate such that one or more channels are formed to produce a template on the surface of the substrate; and (b) printing one or more layers of the conductive ink within the one or more channels In another embodiment, substrates produced by the methods described herein are provided. In another embodiment, systems for implementing the procedures described herein are provided.

### CROSS REFERENCE TO RELATED APPLICATIONS

This application claims priority upon U.S. provisional application Ser. No. 62/744,253, filed on Oct. 11, 2018. This application is hereby incorporated by reference in its entirety for all of its teachings.

### TECHNICAL FIELD

The present disclosure generally relates to systems and methods of printing conductive inks on substrates.

### BACKGROUND

Conductive ink and printed electronics are rapidly growing industries. Despite this growth, issues of printing conductive ink on substrates still linger. Bleed of the ink on the substrate, for example, is one example of a problem surrounding current methodologies. One method to circumvent ink bleed is to create a channel for the ink by laser etching the substrate. This method, however, requires the use of two separate machines to achieve this end—a machine capable of laser etching and a printer for printing the ink. This combination of machinery can be prohibitively expensive. Accordingly, there is a need to address the aforementioned deficiencies and inadequacies. New methods and systems to print conductive ink using inject printers are desired.

### SUMMARY

The present disclosure is directed to overcoming the aforementioned problems and improving the formation of an electrical conductor using additive manufacturing or printing processes and systems. In various aspects methods and systems for forming a conductor by the printing of a conductive ink are provided. Described herein are methods for printing conductive inks on substrates. In one embodiment, the method for printing a conductive ink on a substrate, comprises (a) printing, using a printer, one or more layers of a non-conductive material on a surface of the substrate such that one or more channels are formed to produce a template on the surface of the substrate; and (b) printing one or more layers of the conductive ink within the one or more channels. In another embodiment, substrates produced by the methods described herein are provided. In another embodiment, systems for implementing the procedures described herein are provided.

Other systems, methods, features, and advantages of the present disclosure for ink-jet printing of conductive ink, will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A-1B demonstrate conductive ink on a substrate as printed without a dielectric template. FIG. 1A displays three copies of a silver line without a dielectric template. FIG. 1B displays eighteen (18) copies of a silver line without a dielectric template.

FIGS. 1C-1D demonstrate conductive ink on a substrate as printed by methods according to the present disclosure. FIG. 1C displays three copies of a silver line printed with a dielectric template. FIG. 1B displays eighteen (18) copies of a silver line printed with a dielectric template.

FIG. 2 illustrates an embodiment of a method according to the present disclosure.

FIG. 3 illustrates another embodiment of a method according to the present disclosure.

FIG. 4 illustrates another embodiment of a method according to the present disclosure.

FIG. 5 depicts an apparatus 1010 in which the systems described herein may be coupled to in order to assist in automation of the system.

### DETAILED DESCRIPTION

Described herein are systems and methods for printing conductive inks on substrates. Although particular embodiments are described, those embodiments are mere exemplary implementations of the system and method. One skilled in the art will recognize other embodiments are possible. All such embodiments are intended to fall within the scope of this disclosure. Moreover, all references cited herein are intended to be and are hereby incorporated by reference into this disclosure as if fully set forth herein. While the disclosure will now be described in reference to the above drawings, there is no intent to limit it to the embodiment or embodiments disclosed herein. On the contrary, the intent is to cover all alternatives, modifications and equivalents included within the spirit and scope of the disclosure.

Before the present disclosure is described in greater detail, it is to be understood that this disclosure is not limited to particular embodiments described, as such may, of course, vary. It is also to be understood that the terminology used herein is for the purpose of describing particular embodiments only, and is not intended to be limiting, since the scope of the present disclosure will be limited only by the appended claims.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

It is to be understood that, unless otherwise indicated, the present disclosure is not limited to particular types of methods and systems relating for extracting subject motion in imaging of the subject, and particular software[s] for post-processing and analysis, or the like, as such can vary. It is also to be understood that the terminology used herein is for purposes of describing particular embodiments only, and is not intended to be limiting. It is also possible in the present disclosure that steps can be executed in different sequence where this is logically possible.

It must be noted that, as used in the specification and the appended claims, the singular forms “a,” “an,” and “the” include plural referents unless the context clearly dictates otherwise. Thus, for example, reference to “a channel” includes a plurality of channels. In this specification and in the claims that follow, reference will be made to a number of terms that shall be defined to have the following meanings unless a contrary intention is apparent.

“Optional” or “optionally” means that the subsequently described event or circumstance can or cannot occur, and that the description includes instances where the event or circumstance occurs and instances where it does not. For example, the methods described herein may optionally include the use of a primer layer, where the primer layer may or may not be present.

Throughout this specification, unless the context dictates otherwise, the word “comprise,” or variations such as “comprises” or “comprising,” will be understood to imply the inclusion of a stated element, integer, step, or group of elements, integers, or steps, but not the exclusion of any other element, integer, step, or group of elements, integers, or steps.

As used herein, the term “about” is used to provide flexibility to a numerical range endpoint by providing that a given numerical value may be “a little above” or “a little below” the endpoint without affecting the desired result. For purposes of the present disclosure, “about” refers to a range extending from 10% below the numerical value to 10% above the numerical value. For example, if the numerical value is 10, “about 10” means between 9 and 11 inclusive of the endpoints 9 and 11.

As used herein, a plurality of items, structural elements, compositional elements, and/or materials may be presented in a common list for convenience. However, these lists should be construed as though each member of the list is individually identified as a separate and unique member. Thus, no individual member of any such list should be construed as a de facto equivalent of any other member of the same list based solely on its presentation in a common group, without indications to the contrary.

Disclosed are materials and components that can be used for, can be used in conjunction with, can be used in preparation for, or are products of the disclosed compositions and methods. These and other materials are disclosed herein, and it is understood that when combinations, subsets, interactions, groups, etc. of these materials are disclosed, that while specific reference to each various individual combination and permutation of these compounds may not be explicitly disclosed, each is specifically contemplated and described herein. For example, if a conductive ink is disclosed and discussed, and a number of different non-conductive materials are discussed, each and every combination of conductive ink and non-conductive material that is possible is specifically contemplated unless specifically indicated to the contrary. For example, if a class of conductive inks A, B, and C are disclosed, as well as a class of non-conductive materials D, E, and F, and an example combination of A +D is disclosed, then even if each is not individually recited, each is individually and collectively contemplated. Thus, in this example, each of the combinations A+E, A+F, B+D, B+E, B+F, C+D, C+E, and C+F is specifically contemplated and should be considered from disclosure of A, B, and C; D, E, and F; and the example combination A+D. Likewise, any subset or combination of these is also specifically contemplated and disclosed. Thus, for example, the sub-group of A+E, B+F, and C+E is specifically contemplated and should be considered from disclosure of A, B, and C; D, E, and F; and the example combination of A+D. This concept applies to all aspects of the disclosure including, but not limited to, steps in methods of making and using the disclosed compositions. Thus, if there are a variety of additional steps that can be performed with any specific embodiment or combination of embodiments of the disclosed methods, each such combination is specifically contemplated and should be considered disclosed.

Provided herein are systems and methods for printing conductive inks on a substrate. Systems and methods as described herein allow for higher thickness (for example, in an outward direction from and generally normal or perpendicular to the substrate), resolution, and conductivity of conductive ink. In certain aspects, systems and methods as described herein can prevent the bleed, spread, leaching, or lateral seepage that typically occurs on the printing of an ink, particularly a conductive ink, on a substrate.

In one embodiment, described herein is a method for printing a conductive ink on a substrate, the method comprising:

printing, using a printer, one or more layers of a non-conductive material on a surface of the substrate such that one or more channels are formed to produce a template on the surface of the substrate; and

printing one or more layers of the conductive ink within the one or more channels.

The systems and methods as described herein can print a template comprising one or more channels configured for reception of conductive ink. The design or configuration of the template can be modified as needed depending upon the application. The template can be formed of a non-conductive material. The template can comprise one or more channels within which the conductive ink is printed. The channels of the template can be formed by creating two opposed, spaced apart walls that extend in a direction outwardly from the surface of the substrate and that in various aspects can be generally normal or perpendicular to the substrate, thereby creating a channel within the opposed, spaced apart walls. In one embodiment, the channels printed on the substrate can be connected to form one continuous channel. In another embodiment, the channels can be disconnected. In another embodiment, the substrate can include a combination of continuous and disconnected channels.

The channels printed on the substrate are composed of a non-conductive material. The term “non-conductive material” is any material that is less conductive than the printed conductive material. In one embodiment, the non-conductive material is a UV-cured resin. In another embodiment, the UV-cured resin is derived from one or more ethylenically unsaturated monomers such as, for example, acrylates, methacrylates, diacrylates, dimethacrylates, methacrylamides, diacrylamide, dimethacrylamides, and any combination thereof. In another embodiment, the UV-cured resin is DI-7, OPT-7, or DI-8 manufactured by ChemCubed. In certain embodiments, the non-conductive material can be formulated with other components such as surfactants, solvents, and initiators.

In one embodiment, the channels printed on the substrate can be printed in multiple layers such that the wall height of the channels can be modified as needed. In one embodiment, the channel wall has a height of from about 3 μm to about 500 μm, or about 3 μm, about 5 μm, about 10 μm, about 25 μm, about 50 μm, about 75 μm, about 100 μm, about 125 μm, about 150 μm, about 175 μm, about 200 μm, about 225 μm, about 250 μm, about 275 μm, about 300 μm, about 325 μm, about 350 μm, about 375 pm, about 400 μm, about 425 μm, about 450 μm, about 475 μm, or about 500 μm, where any value can be a lower and upper end-point of a range (e.g., about 10 μm to about 100 μm), and where the height is measured from the surface of the substrate, or, if used, the primer layer as described below to the top of the channel wall.

The width of the channel printed on the substrate can vary as well. In one embodiment the channel has a channel width from about 1 μm to about 1,000 μm, or about 1 μm, about 10 μm, about 25 μm, about 50 μm, about 75 μm, about 100 μm, about 150 μm, about 200 μm, about 250 μm, about 300 μm, about 350 μm, about 400 μm, about 450 μm, about 500 μm, about 550 μm, about 600 μm, about 650 μm, about 700 pm, about 750 μm, about 800 μm, about 850 μm, about 900 μm, about 950 μm, or about 1,000 μm, where any value can be a lower and upper end-point of a range (e.g., about 50 μm to about 200 μm), where the width of the channel is measured between the interior surface of the channel walls.

The dimensions of the channels printed on the substrate can vary depending upon the end-use of the printed substrate. For example, when the printed substrate is used in passive circuitry or low-voltage application, the channel height and width can be reduced (i.e., lower amount of conductive ink is needed). Alternatively, the printed substrates produced herein can include higher amounts of conductive ink for use in high voltage applications (e.g., circuit boards).

In certain embodiments, a primer layer can be applied to the surface of the substrate prior to printing the channels of the template. Depending upon the substrate that is selected, the primer layer can facilitate adhesion between the substrate and the printed channels. In one embodiment, the primer layer is composed of a non-conductive material as described herein. In another embodiment, the non-conductive material is the same material used in the primer layer and channel walls. In another embodiment, the non-conductive material used to produce the primer layer is different than the non-conductive material used to produce the channel walls.

The thickness of the primer layer can vary as well. In one embodiment the primer layer has a thickness from about 3 μm to about 20 μm, or about 3 μm, about 4 pm, about 5 μm, about 6 μm, about 7 μm, about 8 μm, about 9 μm, about 10 μm, about 11 μm, about 12 μm, about 13 μm, about 14 μm, about 15 μm, about 16 μm, about 17 μm, about 18 μm, about 19 μm, or about 20 μm, where any value can be a lower and upper end-point of a range (e.g., about 5 μm to about 15 μm).

After the channels (i.e., template) have been printed on the substrate, a conductive ink is printed within the channels. As used herein, a conductive ink is any material that has a resistivity of less than or equal to about 1×10⁻⁴ Ω/m. In one embodiment, the conductive ink has a resistivity of about 1×10⁻⁹ Ω/m to about 1×10⁻⁴ Ω/m.

In one embodiment, the conductive ink is a metal-organic compound. The distinct term “metal organic compound” refers to metal-containing compounds lacking direct metal-carbon bonds. Examples of metal organic compounds include, but are not limited to, metal β-diketonates, metal alkoxides, metal dialkylamides, and metal phosphine complexes. In another embodiment, the conductive ink is a particle free metal-organic compound. In this aspect, the metal organic compound does not exist as individual particles but can be converted to free particles upon further processing (e.g., sintering). In one embodiment, the conductive ink is a silver organic compound. In another embodiment, the conductive ink is a particle-free silver organic compound.

In another embodiment, the conductive ink can include a plurality of nanoparticles. For example, the conductive ink can be metallonanoparticles including, but not limited to, silver nanoparticles or a copper nanoparticles. In another embodiment, the conductive ink includes silver nanoparticles having an average size of from about 20 nm to about 60 nm, or about 20 μm, about 25 μm, about 30 μm, about 35 μm, about 40 μm, about 45 μm, about 50 μm, about 55 μm, or about 60 μm, where any value can be a lower and upper end-point of a range (e.g., about 25 μm to about 50 μm). In another embodiment, conductive ink is composed of graphene particles.

The amount of conductive ink printed within the channels can vary depending upon the end-use of the printed substrate. The amount of conductive ink printed within the channels in general is such that the ink remains within the channel walls and does not overflow above the channel walls. In one embodiment, the conductive ink has a height from about 1 μm to about 500 μm. Multiple layers of conductive ink can be printed within the channel in order to produce the desired height and amount of conductive ink within the channels of the template.

The methods and systems as described herein use printers to produce the template on the surface of the substrate and subsequently print the conductive ink with the channels of the template. In one embodiment, the printer is an ink-jet printer. Ink-jet printers useful herein can be two-dimensional or three-dimensional printers, for example, FUJIFILM Dimatix Materials Printer DMP-2850, Mimaki® UJF-6042 Flatbed UV Printer (Mk1 or Mk2), or Mimaki® UJV500-160.

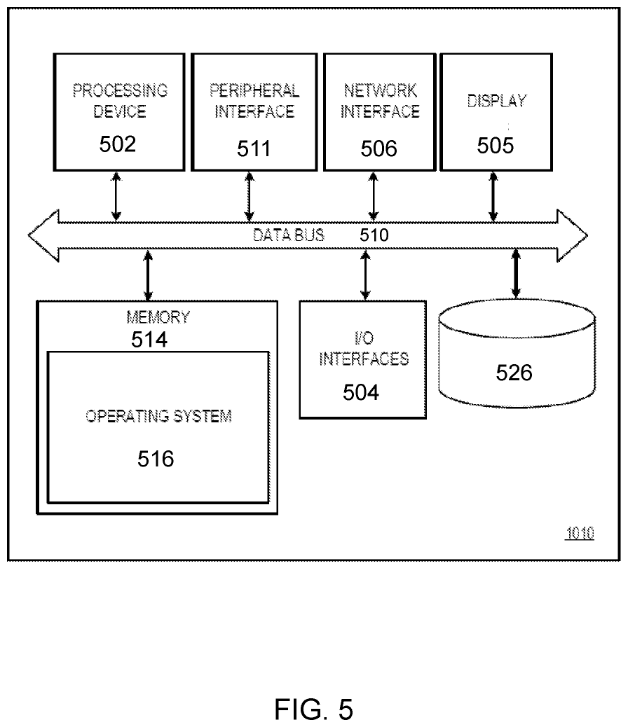

In another embodiment, the printer is a 3-D printer. In one embodiment, the 3-D printer can be an electro UV3D printer. In other embodiments according to the present disclosure, systems as described herein comprise an ink-jet printer coupled to (or in communication with) an apparatus 1010 as embodied in FIG. 5 (and described below). Systems as described herein can further comprise logic stored a non-transitory computer-readable medium executable on a computing device, for example the apparatus 1010.

The systems and methods as described herein can print on the surface of a variety of substrates. In certain embodiments, the surface of the substrate on which the template material and the conductive ink are printed is generally planar. The substrates as described herein can be, for example, a polymer such as, for example, a polyimide, a polyacrylic, a polyester, a polyurethane, or an epoxy resin. In otyer embodiments, the substrate can be composed of fiberglass, glass, paper, cotton-fiber based, and such. Examples of surfaces for printing include (but not limited to) pcb boards (constructed of materials such as FR-4, for example), KAPTON® (polyimide film manufactured by DuPont), PET, labels and paper, PTFE, and the like.

In certain embodiments, after the conductive ink has been printed within the template printed on the substrate, the conductive ink is sintered. In one embodiment, the substrate is heated at a temperature greater than 65° C. In another embodiment, the substrate with conductive ink is heated at a temperature of from about 65° C. to about 400° C., or about 65° C., about 75° C., about 100° C., about 150° C., about 200° C., about 250° C., about 300° C., about 350, or about 400° C., where any value can be a lower and upper end-point of a range (e.g., about 75° C. to about 100° C.). In another embodiment, the conductive ink is sintered at a temperature of about 75° C., about 76° C., about 77° C., about 78° C., about 79° C., about 80° C., about 81° C., about 82° C., about 83° C., about 84° C., or about 85° C., where any value can be a lower and upper end-point of a range (e.g., about 77° C. to about 82° C.).

The sintering of the conductive ink can be performed using a heating element or component. In one embodiment, the heating element is integrated or incorporated into the printer. In another embodiment, the heating element or component is external or separate from the printer.

In certain embodiments, multiple sintering steps can be performed. In one embodiment, the conductive ink is sintered while printing the one or more layers of conductive ink, in between the printing of layers, or after printing of a final layer, or in combination thereof. In another embodiment, after each layer of conductive ink is printed within the channel, the conductive ink is sintered.

Additional process steps can be performed during the production of the printed substrates. For example, the layer of conductive ink can be wiped with a solvent in between the printing of layers, after the printing of the final layer, or both. Suitable solvents include alcohols, such as isopropyl alcohol (IPA) or ethanol, and mineral spirits. The solvent can be wiped using a soft absorbent material, such as a soft microfiber cloth or tissue.

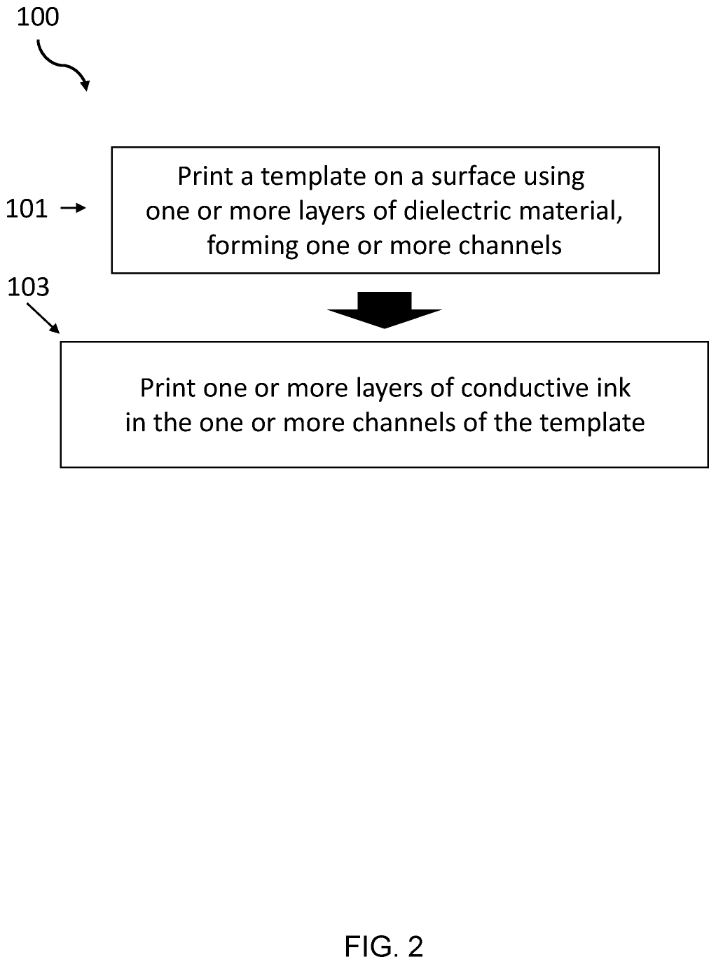

FIGS. 2-4 provide exemplary methods as described herein. FIG. 2 illustrates an exemplary method 100 according to the present disclosure. According to the method 100, first, one or more layers of nonconductive material can be printed to form a template creating the one or more channels within the template 101. Next, one or more layers of conductive ink can be printed within in the channel(s) of the template 103 and sintered. As discussed above, sintering of the conductive ink can be done while printing the conductive layer, in between the printing of layers or after printing of the final layer, or a combination of the above. One or more conductors or conductive pathways can thereby be formed from the sintered conductive ink printed within the one or more channels.

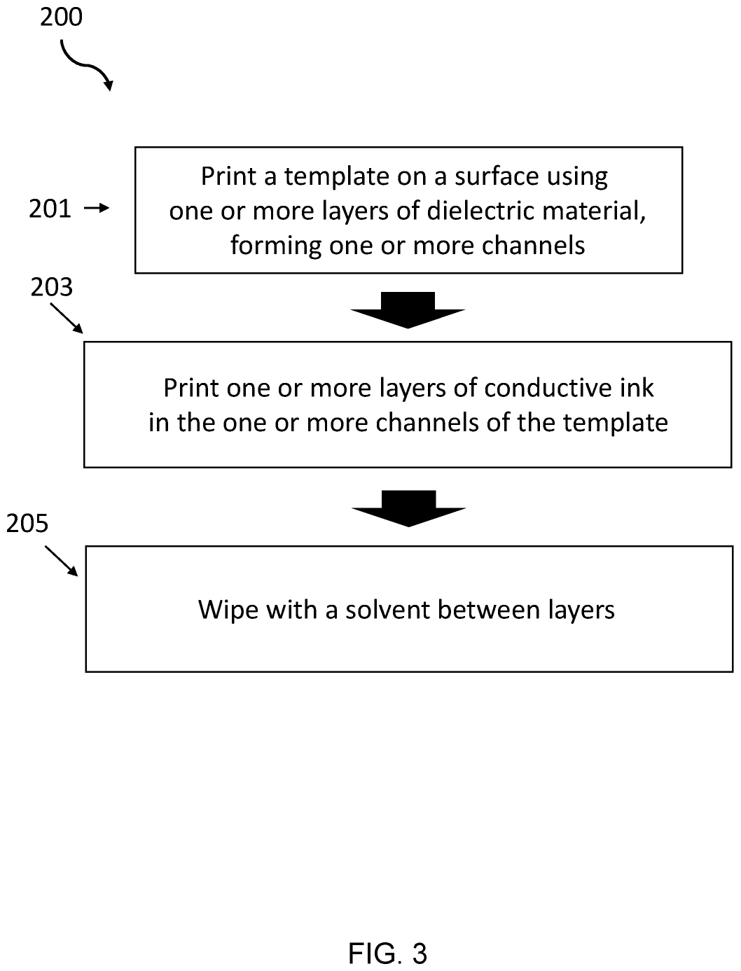

FIG. 3 illustrates another embodiment of a method 200 according to the present disclosure. According to the method 200, first, one or more layers of nonconductive material can be printed to form a template 201. Next, one or more layers of conductive ink can be printed within the channel[s] of the template 203 and sintered. Sintering of the conductive ink can be done while printing the conductive layer, in between layers or after printing of the final layer, or a combination of the above. Third, the printed layers (non-conductive material, conductive ink, or both) can be wiped with a solvent in between the printing of layers 205 or after the printing of the final layer (can be between layers of step 201, 203, or both).

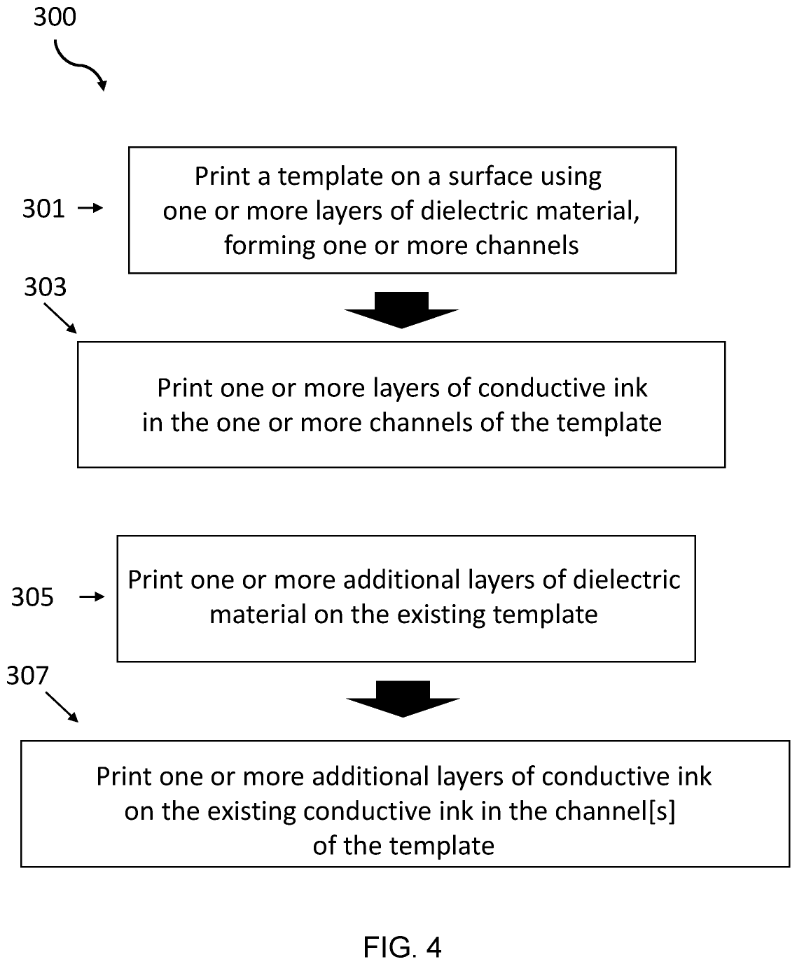

FIG. 4 illustrates a method 300 according to the present disclosure. According to the method 300, first, one or more layers of dielectric or nonconductive material can be printed according to form a template 301. Then, second, one or more layers of conductive ink can be printed within the channels of the dielectric template 303 and sintered. Sintering of the conductive ink can be done while printing the conductive layer, in between layers or after printing of the final layer, or a combination of the above. An additional one or more layers of dielectric or nonconductive material can be printed according to the template 305, and an additional one or more layers of conductive ink can be printed on the existing conductive ink 307. Again, sintering of the conductive ink can be done while printing the conductive layer, in between layers or after printing of the final layer of conductive ink, or a combination of the above. Additionally, the template material, conductive ink, or both can be wiped with a solvent in between layers.

FIG. 5 depicts an apparatus 1010 in which the systems described herein may be coupled to in order to assist in automation of the system. The apparatus 1010 can be embodied in any one of a wide variety of wired and/or wireless computing devices, multiprocessor computing device, and so forth. As shown in FIG. 5, the apparatus 1010 comprises memory 514, a processing device 502 a number of input/output interfaces 504, a network interface 506, a display 505, a peripheral interface 511, and mass storage 526, wherein each of these devices are connected across a local data bus 510. The apparatus 1010 can be coupled to one or more peripheral measurement devices (not shown) connected to the apparatus 1010 via the peripheral interface 511.

The processing device 502 can include any custom made or commercially available processor, a central processing unit (CPU) or an auxiliary processor among several processors associated with the apparatus 1010, a semiconductor based microprocessor (in the form of a microchip), a macroprocessor, one or more application specific integrated circuits (ASICs), a plurality of suitably configured digital logic gates, and other well-known electrical configurations comprising discrete elements both individually and in various combinations to coordinate the overall operation of the computing system.

The memory 514 can include any one of a combination of volatile memory elements (e.g., random-access memory (RAM, such as DRAM, and SRAM, etc.)) and nonvolatile memory elements (e.g., ROM, hard drive, tape, CDROM, etc.). The memory 514 typically comprises a native operating system 516, one or more native applications, emulation systems, or emulated applications for any of a variety of operating systems and/or emulated hardware platforms, emulated operating systems, etc. For example, the applications can include application specific software which may be configured to perform some or all of the methods described herein (Labview, for example). In accordance with such embodiments, the application specific software is stored in memory 514 and executed by the processing device 502. One of ordinary skill in the art will appreciate that the memory 514 can, and typically will, comprise other components which have been omitted for purposes of brevity.

Input/output interfaces 504 provide any number of interfaces for the input and output of data. For example, where the apparatus 1010 comprises a personal computer, these components may interface with one or more user input devices 504. The display 505 can comprise a computer monitor, a plasma screen for a PC, a liquid crystal display (LCD) on a hand held device, or other display device.

In the context of this disclosure, a non-transitory computer-readable medium stores programs for use by or in connection with an instruction execution system, apparatus, or device. More specific examples of a computer-readable medium can include by way of example and without limitation: a portable computer diskette, a random access memory (RAM), a read-only memory (ROM), an erasable programmable read-only memory (EPROM, EEPROM, or Flash memory), and a portable compact disc read-only memory (CDROM) (optical).

With further reference to FIG. 5, network interface device 506 comprises various components used to transmit and/or receive data over a network environment. For example, the network interface 506 can include a device that can communicate with both inputs and outputs, for instance, a modulator/demodulator (e.g., a modem), wireless (e.g., radio frequency (RF)) transceiver, a telephonic interface, a bridge, a router, network card, etc.). The apparatus 1010 can communicate with one or more computing devices via the network interface 506 over a network. The apparatus 1010 may further comprise mass storage 526. The peripheral 511 interface supports various interfaces including, but not limited to IEEE-1394 High Performance Serial Bus (Firewire), USB, thunderbolt, a serial connection, and a parallel connection.

The flow charts of FIGS. 2-4 show examples of functionality that can be implemented in the apparatus 1010 of FIG. 5 combined with an inkjet printer. If embodied in software, each block shown in FIGS. 2-4 can represent a module, segment, or portion of code that comprises program instructions to implement the specified logical function(s). The program instructions may be embodied in the form of source code that comprises machine code that comprises numerical instructions recognizable by a suitable execution system such as the processing device 502 (FIG. 5) in a computer system or other system. The machine code can be converted from the source code, etc. If embodied in hardware, each block may represent a circuit or a number of interconnected circuits to implement the specified logical function(s).

Also, any logic or application described herein that comprises software or code can be embodied in any non-transitory computer-readable medium for use by or in connection with an instruction execution system such as, for example, a processing device 502 in a computer system or other system. In this sense, each may comprise, for example, statements including instructions and declarations that can be fetched from the computer-readable medium and executed by the instruction execution system.

### Aspects

In a first aspect, disclosed herein is a method for printing a conductive ink on a substrate, comprising:

printing, using a printer, one or more layers of a non-conductive material on a surface of the substrate such that one or more channels are formed to produce a template on the surface of the substrate; and

printing one or more layers of the conductive ink within the one or more channels.

In a second aspect, disclosed herein is the method of the first aspect, wherein the substrate comprises a polyimide, a polyacrylic, a polyester, a polyurethane, an epoxy resin, fiberglass, cotton fibers, glass, paper, or any combination thereof.

In a third aspect, disclosed herein is the method of the first aspect, wherein the non-conductive material is a UV-curable resin.

In a fourth aspect, disclosed herein is the method of the third aspect, wherein the UV-curable resin is derived from the polymerization of an acrylate, methacrylate, diacrylate, dimethacrylate, acrylamide, methacrylamide, or any combination thereof.

In a fifth aspect, disclosed herein is the method of the first aspect, wherein the channel has a channel width from about 1 μm to about 1,000 μm.

In a sixth aspect, disclosed herein is the method of the first aspect, wherein prior to step (a), applying a primer layer on the surface of the substrate, wherein the primer layer comprises a non-conductive material.

In a seventh aspect, disclosed herein is the method of the sixth aspect, wherein the primer layer has a thickness of from about 3 μm to about 20 μm.

In an eighth aspect, disclosed herein is the method of the first aspect, wherein the conductive ink comprises a metal organic compound.

In a ninth aspect, disclosed herein is the method of the first aspect, wherein the conductive ink comprises a particle-free metal organic compound.

In a tenth aspect, disclosed herein is the method of the first aspect, wherein the conductive ink comprises a silver organic compound.

In an eleventh aspect, disclosed herein is the method of the first aspect, wherein the conductive ink comprises a particle-free silver organic compound.

In a twelfth aspect, disclosed herein is the method of the first aspect, wherein the conductive ink comprises a nanoparticle.

In a thirteenth aspect, disclosed herein is the method of the first aspect, wherein the conductive ink comprises a metallonanoparticles.

In a fourteenth aspect, disclosed herein is the method of the first aspect, wherein the conductive ink comprises a silver nanoparticle, a copper nanoparticle, a graphene ink, or any combination thereof.

In a fifteenth aspect, disclosed herein is the method of the first aspect, wherein the conductive ink comprises silver nanoparticles having an average size of from about 20 nm to about 60 nm.

In a sixteenth aspect, disclosed herein is the method of the first aspect, wherein the conductive ink has a height from about 1 μm to about 500 μm.

In a seventeenth aspect, disclosed herein is the method of the first aspect, further comprising sintering the conductive ink while printing the one or more layers of conductive ink, in between the printing of layers, or after printing of a final layer, or in combination thereof.

In an eighteenth aspect, disclosed herein is the method of the first aspect, wherein after each layer of conductive ink is printed within the channel, the conductive ink is sintered.

In a nineteenth aspect, disclosed herein is the method of the eighteenth aspect, wherein the conductive ink is sintered at a temperature greater than 65° C.

In a twentieth aspect, disclosed herein is the method of the eighteenth aspect, wherein the conductive ink is sintered at a temperature of about 75° C. to about 85° C.

In a twenty first aspect, disclosed herein is the method of the first aspect, further comprising wiping the one or more printed layers of conductive ink with a solvent in between the printing of layers, after the printing of the final layer, or both.

In a twenty second aspect, disclosed herein is the method of the first aspect, further comprising printing one or more additional layers of non-conductive material on the existing template after printing the one or more layers of conductive ink, adding height to the existing one or more channels.

In a twenty third aspect, disclosed herein is the method of the first aspect, wherein the printer is an inkjet printer or a 3D printer.

In a twenty fourth aspect, disclosed herein is the method of the first aspect, wherein the printer is a FUJIFILM Dimatix Materials Printer DMP-2850, Mimaki® UJF-6042 Flatbed UV Printer (Mk1 or Mk2), Mimaki® UJV500-160, or electro UV3D printer.

In a twenty fifth aspect, disclosed herein is a substrate produced by the methods in any one of aspects one to twenty four.

In a twenty sixth aspect, disclosed herein is a substrate comprising a plurality of channels on a surface of the substrate, wherein the channels comprise non-conductive material, and a conductive ink within the plurality of channels.

In a twenty seventh aspect, disclosed herein is the substrate of the twenty sixth aspect, wherein the non-conductive material is a UV-curable resin.

In a twenty eighth aspect, disclosed herein is the substrate of the twenty sixth aspect, wherein the channel has a channel width from about 1 μm to about 1,000 μm.

In a twenty ninth aspect, disclosed herein is the substrate of the twenty sixth aspect, wherein a primer layer is between the surface of the substrate and the channels, wherein the primer layer comprises a non-conductive material.

In a thirtieth aspect, disclosed herein is the substrate of the twenty ninth aspect, wherein the primer layer has a thickness of from about 3 μm to about 20 μm.

In a thirtieth first aspect, disclosed herein is the substrate of the twenty sixth aspect, wherein the conductive ink comprises a metal organic compound.

In a thirtieth second aspect, disclosed herein is the substrate of the twenty sixth aspect, wherein the conductive ink comprises a particle-free metal organic compound.

In a thirtieth third aspect, disclosed herein is the substrate of the twenty sixth aspect, wherein the conductive ink comprises a silver organic compound.

In a thirtieth fourth aspect, disclosed herein is the substrate of the twenty sixth aspect, wherein the conductive ink comprises a particle-free silver organic compound.

In a thirtieth fifth aspect, disclosed herein is the substrate of the twenty sixth aspect, wherein the conductive ink comprises a nanoparticle.

In a thirtieth sixth aspect, disclosed herein is the substrate of the twenty sixth aspect, wherein the conductive ink comprises a metallonanoparticles.

In a thirtieth seventh aspect, disclosed herein is the substrate of the twenty sixth aspect, wherein the conductive ink comprises a silver nanoparticle, a copper nanoparticle, graphene, or any combination thereof.

In a thirtieth eighth aspect, disclosed herein is the substrate of the twenty sixth aspect, wherein the conductive ink comprises silver nanoparticles having an average size of from about 20 nm to about 60 nm.

In a thirtieth ninth aspect, disclosed herein is the substrate of the twenty sixth aspect, wherein the conductive ink has a height from about 1 μm to about 500 μm.

In a fortieth aspect, disclosed herein is the substrate of the twenty sixth aspect, wherein the conductive ink is sintered.

In a forty first aspect, disclosed herein is a system, comprising:
a printer; and
logic comprising the methods of any of aspects one to twenty four, wherein the logic is stored on a non-transitory computer-readable medium.

In a forty second aspect, disclosed herein is the system of the forty first aspect, further comprising a computing device

In a forty third aspect, disclosed herein is the system of the forty first aspect, herein the logic is executable on the computing device.

In a forty fourth aspect, disclosed herein is method for printing a conductive ink on a substrate, comprising:

printing, using a printer, one or more layers of a non-conductive material on a surface of the substrate such that one or more channels are formed to produce a template on the surface of the substrate; and

printing one or more layers of the conductive ink within the one or more channels.

In a forty fifth aspect, disclosed herein is the method of the forty fourth aspect, wherein the substrate comprises a polyimide, a polyacrylic, a polyester, a polyurethane, an epoxy resin, fiberglass, cotton fibers, glass, paper, or any combination thereof.

In a forty sixth aspect, disclosed herein is the method of aspects 44 or 45, wherein the non-conductive material is a UV-curable resin.

In a forty seventh aspect, disclosed herein is the method of aspect 46, wherein the UV-curable resin is derived from the polymerization of an acrylate, methacrylate, diacrylate, dimethacrylate, acrylamide, methacrylamide, or any combination thereof.

In a forty eighth aspect, disclosed herein is the method in any one aspects 44-47, wherein the channel has a channel width from about 1 μm to about 1,000 μm.

In a forty ninth aspect, disclosed herein is the method in any one of aspects 44-48, wherein prior to step (a), applying a primer layer on the surface of the substrate, wherein the primer layer comprises a non-conductive material.

In a fiftieth aspect, disclosed herein is the method of aspect 49, wherein the primer layer has a thickness of from about 3 μm to about 20 μm.

In a fifty first aspect, disclosed herein is the method in any one of aspects 44-50, wherein the conductive ink comprises a metal organic compound.

In a fifty second aspect, disclosed herein is the method in any one of aspects 44-50, wherein the conductive ink comprises a particle-free metal organic compound.

In a fifty third aspect, disclosed herein is the method in any one of aspects 44-50, wherein the conductive ink comprises a silver organic compound.

In a fifty fourth aspect, disclosed herein is the method in any one of aspects 44-50, wherein the conductive ink comprises a particle-free silver organic compound.

In a fifty fifth aspect, disclosed herein is the method in any one of aspects 44-50, wherein the conductive ink comprises a nanoparticle.

In a fifty sixth aspect, disclosed herein is the method in any one of aspects 44-50, wherein the conductive ink comprises a metallonanoparticles.

In a fifty seventh aspect, disclosed herein is the method in any one of aspects 44-50, wherein the conductive ink comprises a silver nanoparticle, a copper nanoparticle, graphene, or any combination thereof.

In a fifty eighth aspect, disclosed herein is the method in any one of aspects 44-50, wherein the conductive ink comprises silver nanoparticles having an average size of from about 20 nm to about 60 nm.

In a fifty ninth aspect, disclosed herein is the method in any one of aspects 44-58, wherein the conductive ink has a height from about 1 μm to about 500 μm.

In a sixtieth aspect, disclosed herein is the method in any one of aspects 44-59, further comprising sintering the conductive ink while printing the one or more layers of conductive ink, in between the printing of layers, or after printing of a final layer, or in combination thereof.

In a sixty first aspect, disclosed herein is the method in any one of aspects 44-58, wherein after each layer of conductive ink is printed within the channel, the conductive ink is sintered.

In a sixty second aspect, disclosed herein is the method of aspect 61, wherein the conductive ink is sintered at a temperature greater than 65° C.

In a sixty third aspect, disclosed herein is the method of aspect 61, wherein the conductive ink is sintered at a temperature of about 75° C. to about 85° C.

In a sixty fourth aspect, disclosed herein is the method in any one of aspects 44-63, further comprising wiping the one or more printed layers of conductive ink with a solvent in between the printing of layers, after the printing of the final layer, or both.

In a sixty fifth aspect, disclosed herein is the method in any one of aspects 44-64, further comprising printing one or more additional layers of non-conductive material on the existing template after printing the one or more layers of conductive ink, adding height to the existing one or more channels.

In a sixty sixth aspect, disclosed herein is the method in any one of aspects 44-65, wherein the printer is an inkjet printer or a 3D printer.

In a sixty seventh aspect, disclosed herein is the method in any one of aspects 44-65, wherein the printer is a FUJIFILM Dimatix Materials Printer DMP-2850, Mimaki® UJF-6042 Flatbed UV Printer (Mk1 or Mk2), Mimaki® UJV500-160, or electro UV3D printer.

In a sixty eighth aspect, disclosed herein is a substrate produced by the method in any one of aspects 44-67.

In a sixty ninth aspect, disclosed herein is a substrate comprising a plurality of channels on a surface of the substrate, wherein the channels comprise non-conductive material, and a conductive ink within the plurality of channels.

In a seventieth aspect, disclosed herein is the substrate of aspect 69, wherein the non-conductive material is a UV-curable resin.

In a seventy first aspect, disclosed herein is the substrate of aspects 69 or 70, wherein the channel has a channel width from about 1 μm to about 1,000 μm.

In a seventy second aspect, disclosed herein is the substrate in any one of aspects 69-71, wherein a primer layer is between the surface of the substrate and the channels, wherein the primer layer comprises a non-conductive material.

In a seventy third aspect, disclosed herein is the substrate of aspect 72, wherein the primer layer has a thickness of from about 3 μm to about 20 μm.

In a seventy fourth aspect, disclosed herein is the substrate in any one of aspects 69-73, wherein the conductive ink comprises a metal organic compound.

In a seventy fifth aspect, disclosed herein is the substrate in any one of aspects 69-73, wherein the conductive ink comprises a particle-free metal organic compound.

In a seventy sixth aspect, disclosed herein is the substrate in any one of aspects 69-73, wherein the conductive ink comprises a silver organic compound.

In a seventy seventy aspect, disclosed herein is the substrate in any one of aspects 69-73, wherein the conductive ink comprises a particle-free silver organic compound.

In a seventy eighth aspect, disclosed herein is the substrate in any one of aspects 69-73, wherein the conductive ink comprises a nanoparticle.

In a seventy ninth aspect, disclosed herein is the substrate in any one of aspects 69-73, wherein the conductive ink comprises a metallonanoparticles.

In an eightieth aspect, disclosed herein is the substrate in any one of aspects 69-73, wherein the conductive ink comprises a silver nanoparticle, a copper nanoparticle, graphene, or any combination thereof.

In an eighty first aspect, disclosed herein is the substrate in any one of aspects 69-73, wherein the conductive ink comprises silver nanoparticles having an average size of from about 20 nm to about 60 nm.

In an eighty second aspect, disclosed herein is the substrate in any one of aspects 69-81, wherein the conductive ink has a height from about 1 μm to about 500 μm.

In an eighty third aspect, disclosed herein is the substrate in any one of aspects 69-82, wherein the conductive ink is sintered.

In an eighty fourth aspect, disclosed herein is a system, comprising:
a printer; and
logic comprising the methods of any of aspects 44-67, wherein the logic is stored on a non-transitory computer-readable medium.

In an eighty fifth aspect, disclosed herein is the system of aspect 84, further comprising a computing device.

In an eighty sixth aspect, disclosed herein is the system of aspect 84, wherein the logic is executable on the computing device.

### EXAMPLES

Now having described various embodiments of the disclosure, in general, the examples below describe some additional embodiments. While embodiments of the present disclosure are described in connection with the examples and the corresponding text and figures, there is no intent to limit embodiments of the disclosure to these descriptions. On the contrary, the intent is to cover all alternatives, modifications, and equivalents included within the spirit and scope of embodiments of the present disclosure

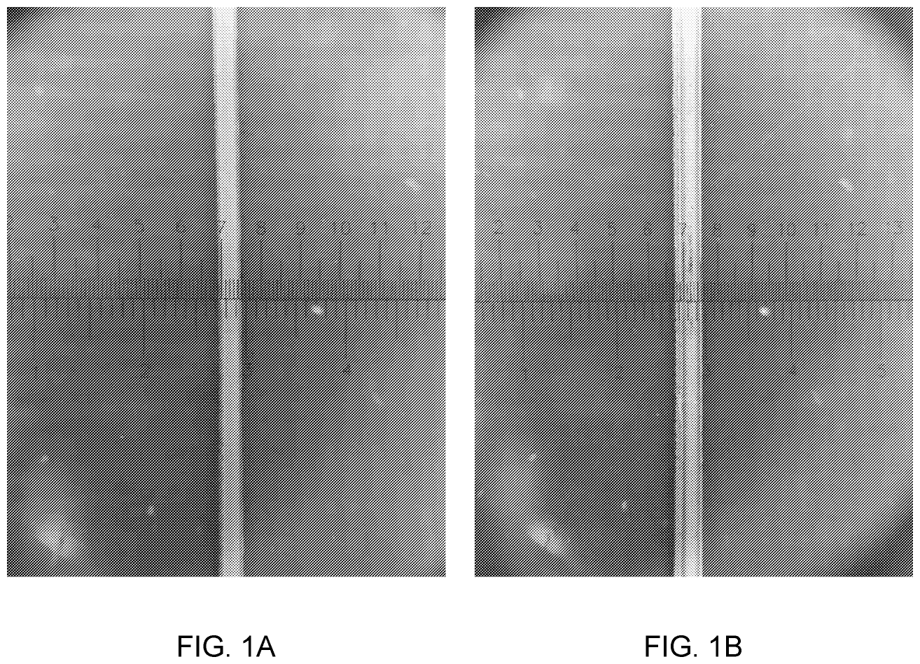

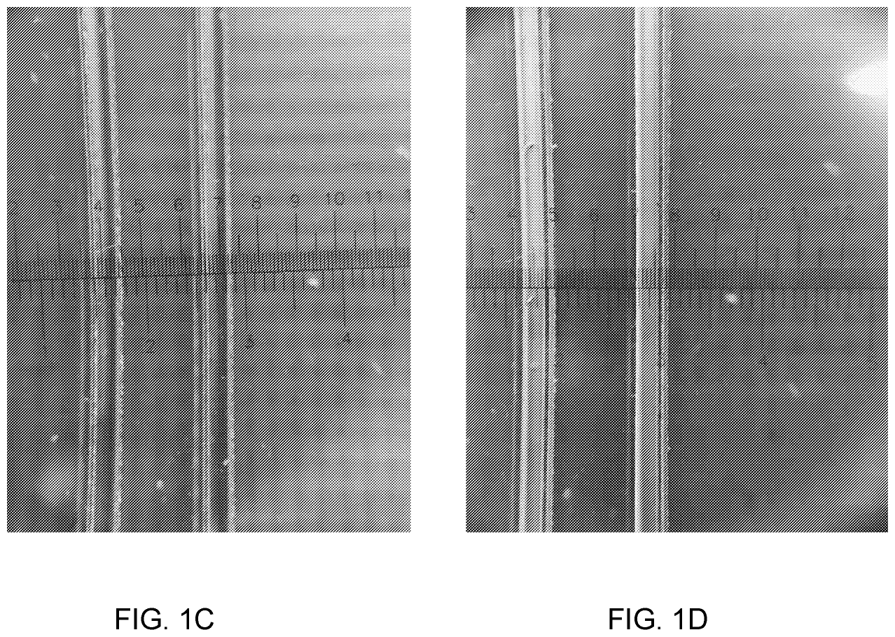

Provided in this example are systems and methods of ink-jet printing conductive ink. FIGS. 1A-1D illustrate images of ink-jet printed conductive silver ink. The images of the printed silver line or conductor depict: (a) the three copies (layers) of conductive silver ink forming a silver line or conductor without a template (FIG. 1A); (b), eighteen copies (layers) of conductive silver ink forming a silver line or conductor without a template (FIG. 1B); (c) the three copies (layers) of conductive silver ink forming a silver line or conductor within a channel formed by a template (FIG. 1C); and (d), eighteen copies (layers) of silver conductive ink forming a silver line or conductor within a channel formed by a template (FIG. 1D).

In FIGS. 1A-1D, images of the printed silver line are shown under different printing conditions. The width of the silver line has been set as 0.38 mm in the software controlling the ink-jet printer. From the images, an obvious width expansion (lateral bleeding, leaching or seepage) can be seen in FIGS. 1A and 1B, where there is no template, due to the silver ink wetting phenomenon during the printing process. In this condition, the accuracy of printed silver line is inversely proportional to the amount of the layers of conductive ink. The error percentage is around 44% (0.55 mm) when there are only three copies (layers) of conductive ink forming the printed silver line, which is over 200% for 18 copies (layers) of conductive ink forming the printed silver line. In contrast, the templated printed silver line maintains a better accuracy from 3 copies (layers) (FIG. 1C) to 18 copies (layers) (FIG. 1D) of printed conductive silver ink, which is smaller than 5%. The data is summarized in Table 1 below for 3 copies (layers) and 18 copies (layers), as well as for additional numbers of copies (layers).

TABLE 1

| | Silver | Silver | Silver | Measured | Measured | Dielectric |
|---|---|---|---|---|---|---|
| | Thickness | Resistance(Ohm) | Resistance(Ohm) | width With | width No | Thickness |
| Layers | (um) | With Dielectric | No Dielectric | dielectric | dielectric | (um) |
| 1 | 7.74 | 9.6 | 11.9 | .4 | .55 | — |
| 3 | 10.42 | 1.4 | 1.7 | .4 | .55 | — |
| 5 | 12.28 | 0.9 | 1.3 | .4 | .67 | 189 |
| 10 | 14.89 | 0.3 | 1.1 | .4 | | 351 |
| 13 | 17.12 | 0.2 | 0.8 | .4 | | — |
| 15 | 21.21 | 0.2 | 0.6 | .4 | | — |
| 18 | 24.44 | 0.1 | 0.3 | .4 | .8 | — |

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

1. A method for printing a conductive ink on a substrate, comprising:
(a) printing, using a printer, one or more layers of a non-conductive material on a surface of the substrate such that one or more channels are formed to produce a template on the surface of the substrate; and
(b) printing one or more layers of the conductive ink within the one or more channels.

2. The method of claim 1, wherein the substrate comprises a polyimide, a polyacrylic, a polyester, a polyurethane, an epoxy resin, fiberglass, cotton fibers, glass, paper, or any combination thereof.

3. The method of claim 1, wherein the non-conductive material is a UV-curable resin.

4. The method of claim 3, wherein the UV-curable resin is derived from the polymerization of an acrylate, methacrylate, diacrylate, dimethacrylate, acrylamide, methacrylamide, or any combination thereof.

5. The method of claim 1, wherein the channel has a channel width from about 1 μm to about 1,000 μm.

6. The method of claim 1, wherein prior to step (a), applying a primer layer on the surface of the substrate, wherein the primer layer comprises a non-conductive material.

7. The method of claim 6, wherein the primer layer has a thickness of from about 3 μm to about 20 μm.

8. The method of claim 1, wherein the conductive ink comprises a metal organic compound.

9. The method of claim 1, wherein the conductive ink comprises a particle-free metal organic compound.

10. The method of claim 1, wherein the conductive ink comprises a silver organic compound.

11. The method of claim 1, wherein the conductive ink comprises a particle-free silver organic compound.

12. The method of claim 1, wherein the conductive ink comprises a nanoparticle.

13. The method of claim 1, wherein the conductive ink comprises a metallonanoparticle

14. The method of claim 1, wherein the conductive ink comprises a silver nanoparticle, a copper nanoparticle, graphene, or any combination thereof.

15. The method of claim 1, wherein the conductive ink comprises silver nanoparticles having an average size of from about 20 nm to about 60 nm.

16. The method of claim 1, wherein the conductive ink has a height from about 1 μm to about 500 μm.

17. The method of claim 1, further comprising sintering the conductive ink while printing the one or more layers of conductive ink, in between the printing of layers, or after printing of a final layer, or in combination thereof.

18. The method of claim 1, wherein after each layer of conductive ink is printed within the channel, the conductive ink is sintered.

19. The method of claim 18, wherein the conductive ink is sintered at a temperature greater than 65° C.

20. The method of claim 18, wherein the conductive ink is sintered at a temperature of about 75° C. to about 85° C.

21. The method of claim 1, further comprising wiping the one or more printed layers of conductive ink with a solvent in between the printing of layers, after the printing of the final layer, or both.

22. The method of claim 1, further comprising printing one or more additional layers of non-conductive material on the existing template after printing the one or more layers of conductive ink, adding height to the existing one or more channels.

23. The method of claim 1, wherein the printer is an inkjet printer or a 3D printer.

24. (canceled)

25. The substrate produced by the method of claim 1.

26. A substrate comprising a plurality of channels on a surface of the substrate, wherein the channels comprise non-conductive material, and a conductive ink within the plurality of channels.

27. A system, comprising:
a printer; and
logic comprising the methods of any of claims 1-24, wherein the logic is stored on a non-transitory computer-readable medium.

28. The system of claim 27, further comprising a computing device.

29. The system of claim 27, wherein the logic is executable on the computing device.
